(19) United States
(12) Patent Application Publication
(10) Pub. No.: US 2004/0198303 A1
(43) Pub. Date: Oct. 7, 2004

(54) Ventilator having the incoming call and ringing doorbell notification functions

(76) Inventors: Chao-Cheng Chiang, Taichung Hsien (TW); Chi-Hsiung Chiang, Taichung Hsien (TW)

Correspondence Address: Chao-Cheng Chiang, 335, Ta Lin Rd., Ta Ya Hsiang, Taichung Hsien, TW

(21) Appl. No.: 10/336,774

(22) Filed: Jan. 2, 2003

(51) Int. Cl. H05K 11/00

(52) U.S. Cl. 455/344; 455/74; 455/556.1; 455/66.1

(57) ABSTRACT

A ventilator includes a power supply circuit, a wireless transceiver module, a central processing unit, a telephone set, and a doorbell set. Thus, the ventilator can notify the user of presence of the incoming call during operation, so that the user can work in the kitchen without missing the incoming call from the telephone set. In addition, the ventilator can notify the user that the doorbell of the doorbell set rings during operation, so that the user can work in the kitchen without missing the doorbell rings from the doorbell set.

### BACKGROUND OF THE INVENTION

1. Field of the Invention

The present invention relates to a ventilator having the incoming ca and ringing doorbell notification functions, and more particularly to a ventilator that can notify the user of the incoming call and the ringing doorbell.

2. Description of the Related Art

The ventilator usually comprises a fan motor that is operated at a high rotational speed, so as to drain the oily smoke contained in the kitchen outward, thereby achieving the ventilating effect. However, the fan motor is operated at a high rotational speed, so that the user working in the kitchen cannot clearly hear the telephone ring or the doorbell ring during operation of the ventilator, thereby easily missing the incoming call or the visitor when the ventilator is in operation.

### SUMMARY OF THE INVENTION

The present invention has arisen to mitigate and/or obviate the disadvantage of the conventional ventilator.

The primary objective of the present invention is to provide a ventilator that can notify the user of presence of the incoming call during operation, so that the user can work in the kitchen without missing the incoming call from the telephone set.

Another objective of the present invention is to provide a ventilator that can notify the user that the doorbell of the doorbell set rings during operation, so that the user can work in the kitchen without missing the doorbell rings from the doorbell set.

A further objective of the present invention is to provide a ventilator comprising a buzzer that emits special sound to remind the user of presence of the incoming call or notify the user that the doorbell of the doorbell set rings during operation.

A further objective of the present invention is to provide a ventilator that comprises a remote controller for controlling the panel push button circuit, so that the remote controller can be used to control the ventilator to be disposed at a muting state or a closed state when taking the incoming call or visiting the visitor, thereby enhancing the versatility and utility of the ventilator.

In accordance with the present invention, there is provided a ventilator, comprising a wireless transceiver module, a central processing unit, a telephone set, and a doorbell set, wherein:

the central processing unit is electrically connected to the wireless transceiver module;

the telephone set includes a first wireless transmitter module, and the first wireless transmitter module transmits a wireless signal that is received by the wireless transceiver module; and

the doorbell set is electrically connected to a second wireless transmitter module, and the second wireless transmitter module transmits a wireless signal that is received by the wireless transceiver module.

Further benefits and advantages of the present invention will become apparent after a careful reading of the detailed description with appropriate reference to the accompanying drawings.

### BRIEF DESCRIPTION OF THE DRAWINGS

FIG. 1 is a schematic perspective view of a ventilator having a muting device in accordance with a preferred embodiment of the present invention;

FIG. 1A is a partially plan enlarged view of the ventilator having a muting device as shown in FIG. 1;

FIG. 2 is a schematic circuit diagram of the ventilator having a muting device in accordance with the preferred embodiment of the present invention.

FIG. 2A is a schematic circuit diagram of a telephone set of the ventilator having a muting device in accordance with the preferred embodiment of the present invention; and

FIG. 2B is a schematic circuit diagram of a doorbell set of the ventilator having a muting device in accordance with the preferred embodiment of the present invention.

### DETAILED DESCRIPTION OF THE INVENTION

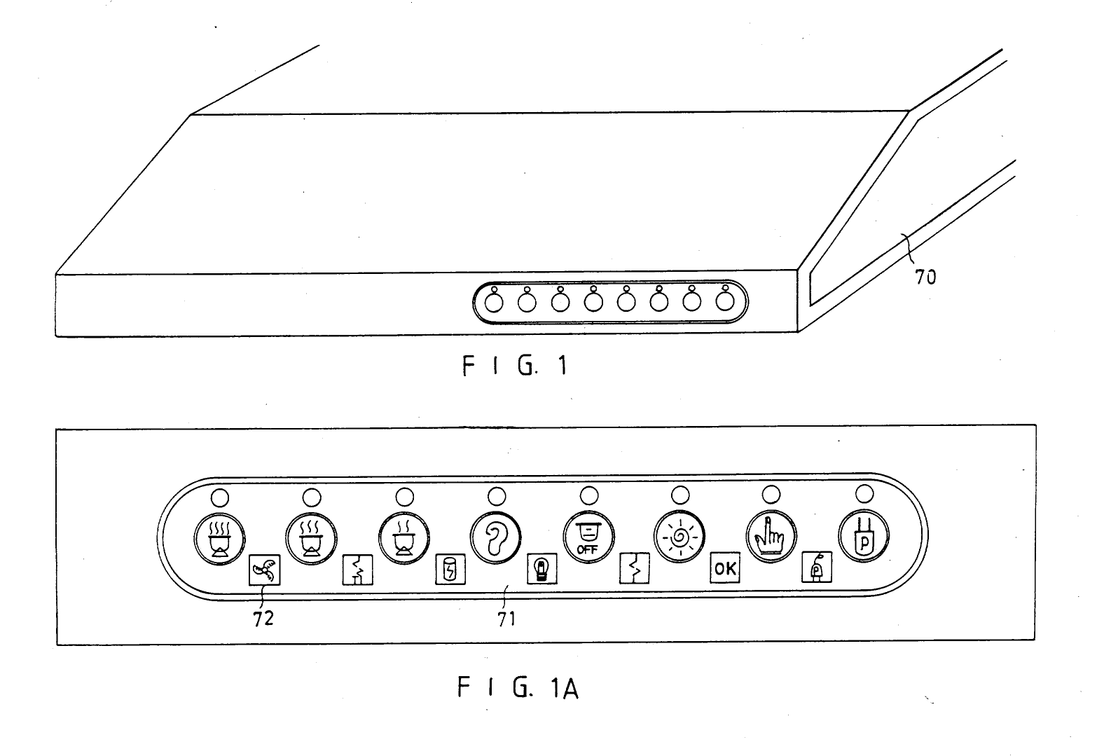

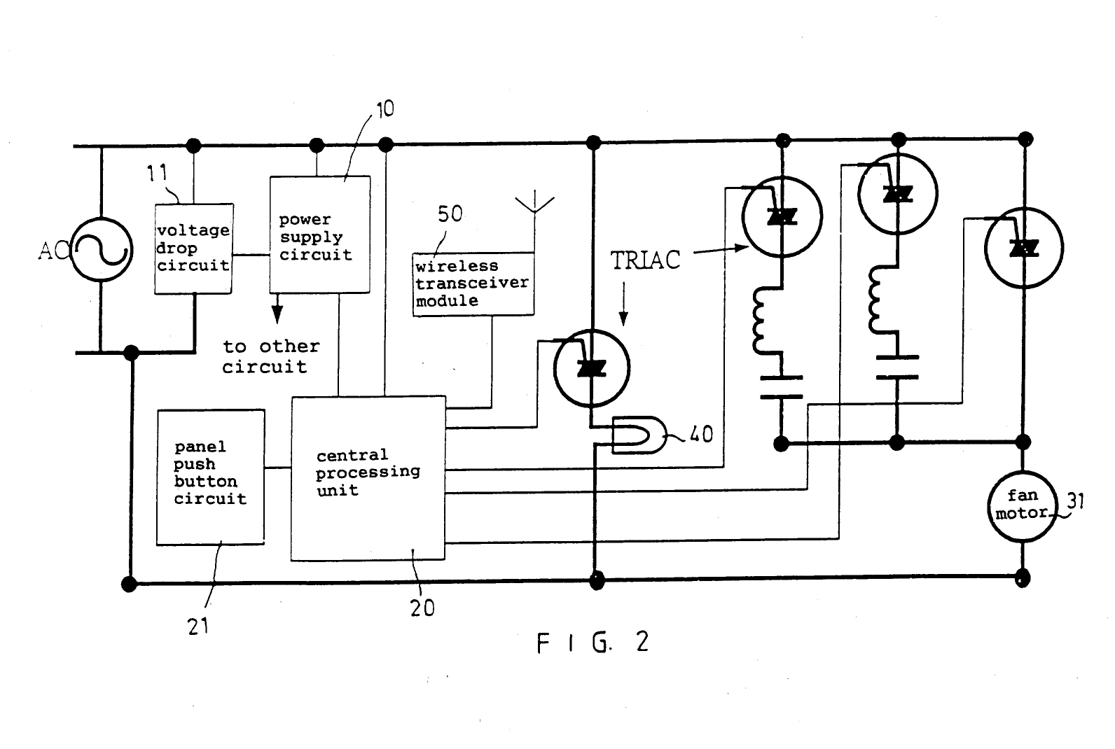

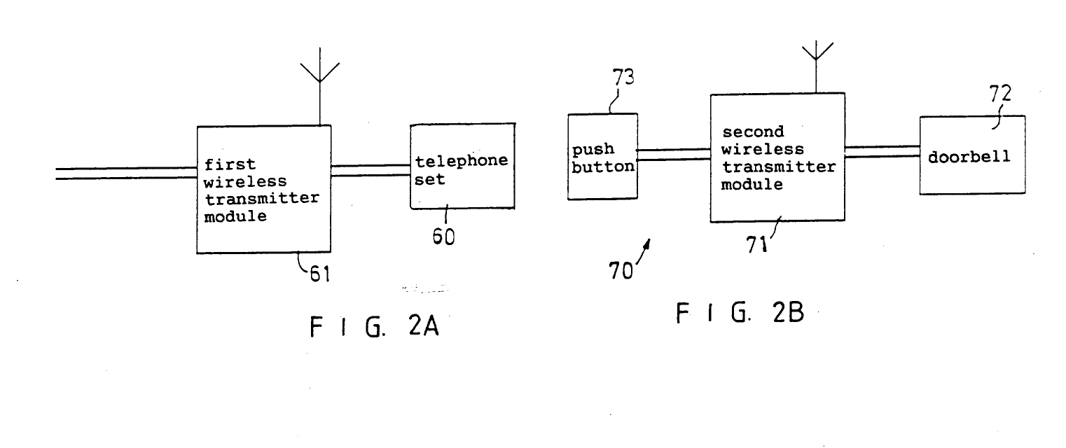

Referring to FIGS. 1, 1A, 2, 2A and 2B, a ventilator in accordance with a preferred embodiment of the present invention comprises a power supply circuit 10, a central processing unit (CPU) 20, a telephone set 60, and a doorbell set 70.

The power supply circuit 10 is connected to a voltage drop circuit 11, so as to convert the alternating current power of the power supply circuit 10 into a direct current power supply.

The central processing unit 20 is connected to a panel push button circuit 21, so that the central processing unit 20 is controlled by the panel push button circuit 21, The central processing unit 20 is electrically connected to the power supply circuit 10. The central processing unit 2Q can be used to control a fan motor 31 of the ventilator 30. The central processing unit 20 is connected to an illumination lamp 40 of the ventilator 30. The central processing unit 20 is electrically connected to a wireless transceiver module 50.

The telephone set 60 includes a first wireless transmitter module 61. The first wireless transmitter module 61 has a mute button (not shown). The first wireless transmitter module 61 transmits a wireless signal that can be received by the wireless transceiver module 50.

The doorbell set 70 is electrically connected to a second wireless transmitter module 71. The second wireless transmitter module 71 transmits a wireless signal that can be received by the wireless transceiver module 50.

In operation, the central processing unit 20 can be used to control the ventilator 30 efficiently and safely. The user can control the panel 32 of the ventilator 30, to control the central processing unit 20 by the panel push button circuit 21, so that the fan motor 31 of the ventilator 30 is controlled and operated by the program in the inside of the central processing unit 20, so as to drain the oily smoke contained in the kitchen outward, thereby achieving the ventilating effect.

When the telephone set 60 rings during operation of the ventilator 30, the first wireless transmitter module 61 detects that the telephone set 60 rings, and then transmits a wireless signal that can be received by the wireless transceiver module 50. Then, the wireless transceiver module 50 feeds back the detected wireless signal to the central processing unit 20 which sends a signal to the illumination lamp 40, so that the illumination lamp 40 blinks to indicate and notify the user of presence of the incoming call. Thus, the ventilator 30 can notify the user of presence of the incoming call during operation. When the user takes the telephone set 60, the first wireless transmitter module 61 is closed immediately, so that the illumination lamp 40 is returned to the original state.

At this time, if the sound of operation of the ventilator 30 is too noisy, the user can press the mute button on the first wireless transmitter module 61, so that the first wireless transmitter module 61 transmits a wireless signal that can be received by the wireless transceiver module 50 which feeds back the detected wireless signal to the central processing unit 20 which sends a signal to the ventilator 30, so as to reduce the rotation speed of the fan motor 31, thereby turning the operation of the ventilator 30 into a mute state. After the user hangs up the telephone set 60, the user can press the mute button on the first wireless transmitter module 61 again, so that the first wireless transmitter module 61 transmits a wireless signal that can be received by the wireless transceiver module 50 which feeds back the detected wireless signal to the central processing unit 20 which sends a signal to the ventilator 30, so as to increase the rotation speed of the fan motor 31, thereby turning the operation of the ventilator 30 into the original state.

Thus, the ventilator 30 can notify the user of presence of the incoming call during operation, so that the user can work in the kitchen without missing the incoming call from the telephone set 60.

Similarly, when the doorbell 72 of the doorbell set 70 rings (when an visitor presses the push button 73 of the doorbell 72) during operation of the ventilator 30, the second wireless transmitter module 71 detects that the doorbell 72 of the doorbell set 70 rings and then transmits a wireless signal that can be received by the wireless transceiver module 50. Then, the wireless transceiver module 50 feeds back the detected wireless signal to the central processing unit 20 which sends a signal to the illumination lamp 40, so that the illumination-lamp 40 blinks to indicate and notify the user that the doorbell 72 of the doorbell set 70 rings. Thus, the ventilator 30 can notify the user that the doorbell 72 of the doorbell set 70 rings during operation. When the user takes the answering phone (not shown) of the doorbell 72 of the doorbell set 70, the second wireless transmitter module 71 is closed immediately, so that the illumination lamp 40 is returned to the original state.

Thus, the ventilator 30 can notify the user that the doorbell 72 of the doorbell set 70 rings during operation, so that the user can work in the kitchen without missing the doorbell rings from the doorbell set 70.

In addition, the ventilator in accordance with the present invention further comprises a buzzer (not shown) that emits special sound to remind the user of presence of the incoming call or notify the user that the doorbell 72 of the doorbell set 70 rings during operation. The buzzer is electrically connected to the central processing unit 20.

Further, the ventilator in accordance with the present invention further comprises a remote controller (not shown) for controlling the panel push button circuit 21, so that the remote controller can be used to control the ventilator to be disposed at a muting state or a closed state when taking the incoming call or visiting the visitor, thereby enhancing the versatility and utility of the ventilator.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

What is claimed is:

1. A ventilator, comprising a wireless transceiver module, a central processing unit, a telephone set, and a doorbell set, wherein:
the central processing unit is electrically connected to the wireless transceiver module;
the telephone set includes a first wireless transmitter module, and the first wireless transmitter module transmits a wireless signal that is received by the wireless transceiver module; and
the doorbell set is electrically connected to a second wireless transmitter module, and the second wireless transmitter module transmits a wireless signal that is received by the wireless transceiver module.

2. The ventilator in accordance with claim 1 further comprising a power supply circuit connected to a voltage drop circuit, so as to convert an alternating current power of the power supply circuit into a direct current power supply.

3. The ventilator in accordance with claim 1, wherein the central processing unit is connected to a panel push button circuit, so that the central processing unit is controlled by the panel push button circuit.

4. The ventilator in accordance with claim 2, wherein the central processing unit is electrically connected to the power supply circuit.

5. The ventilator in accordance with claim 1, wherein the central processing unit is used to control a fan motor of the ventilator.

6. The ventilator in accordance with claim 1, wherein the central processing unit is connected to an illumination lamp of the ventilator.

7. The ventilator in accordance with claim 1, wherein the first wireless transmitter module has a mute button.

8. The ventilator in accordance with claim 1, further comprising a buzzer electrically connected to the central processing unit.

9. The ventilator in accordance with claim 1, further comprising a remote controller for controlling the panel push button circuit.
